(19) United States
(12) Patent Application Publication
(10) Pub. No.: US 2025/0241173 A1
(43) Pub. Date: Jul. 24, 2025

(54) ELECTRONIC DEVICE

(71) Applicant: InnoLux Corporation, Miao-Li County (TW)

(72) Inventors: Chih-Yu LIN, Miao-Li County (TW); Chao-Li CHUANG, Miao-Li County (TW)

(21) Appl. No.: 18/978,312

(22) Filed: Dec. 12, 2024

(30) Foreign Application Priority Data
Jan. 18, 2024 (CN) 202410074173.1

(51) Int. Cl. H10K 59/80

(52) U.S. Cl. CPC H10K 59/8722; H10K 59/873

(57) ABSTRACT

Electronic devices are provided. The electronic device includes a first substrate, a second substrate, a plurality of electronic units, an optical layer, a first sealing layer, and a second sealing layer. The second substrate is disposed opposite to the first substrate. The plurality of electronic units is disposed between the first substrate and the second substrate. The optical layer is disposed between a portion of the plurality of electronic units and the second substrate. The first sealing layer is disposed between another portion of the plurality of electronic units and the second substrate and surrounds the optical layer. The second sealing layer is disposed between the first substrate and the second substrate and surrounds the first sealing layer. Wherein, with respect to a visible light, a difference between a transmittance of the first sealing layer and a transmittance of the optical layer is less than 5%.

### CROSS REFERENCE TO RELATED APPLICATIONS

This application claims priority of China Patent Application No. CN 202410074173.1, filed on Jan. 18, 2024, the entirety of which is incorporated by reference herein.

### TECHNICAL FIELD

Some embodiments of the present disclosure relate to an electronic device, and, in particular, to an electronic device including a sealing layer.

### BACKGROUND

Electronic devices including electronic units, such as displays, smartphones, tablets, notebook computers, and televisions, have become indispensable necessities in modern society. With the booming development of this type of electronic devices, consumers have high expectations of the quality, functionality, or price of these electronic devices.

In general, in the process of manufacturing electronic devices, it is often necessary to use various bonding elements to perform the bonding process, so that different substrates are bonded with each other to obtain the electronic device. Therefore, once the reliability of the bonding element is insufficient, problems may arise such as reducing the visual effect, resolution, reliability, yield, and/or process window of the electronic device. In addition, it may also cause the problem that the electronic device is not easily applicable to narrow frame devices.

Therefore, these electronic devices do not meet consumer expectations in all respects, and there are still some problems in the electronic devices. The development of improved electronic devices remains one of the current goals.

### SUMMARY

In some embodiments, an electronic device is provided. The electronic device includes a first substrate, a second substrate, a plurality of electronic units, an optical layer, a first sealing layer, and a second sealing layer. The second substrate is disposed opposite to the first substrate. The plurality of electronic units is disposed between the first substrate and the second substrate. The optical layer is disposed between a portion of the plurality of electronic units and the second substrate. The first sealing layer is disposed between another portion of the plurality of electronic units and the second substrate and surrounds the optical layer. The second sealing layer is disposed between the first substrate and the second substrate and surrounds the first sealing layer. Wherein, with respect to a visible light, a difference between a transmittance of the first sealing layer and a transmittance of the optical layer is less than 5%.

In some embodiments, an electronic device is provided. The electronic device includes a first substrate, a second substrate, a plurality of electronic units, an optical layer, a sealing layer, and a separator. The first substrate has an active area and a peripheral area surrounding the active area. The second substrate is disposed opposite to the first substrate. The plurality of electronic units is disposed between the active area and the second substrate. The optical layer is disposed between a portion of the plurality of electronic units and the second substrate. The sealing layer is disposed between another portion of the plurality of electronic units and the second substrate and between the peripheral area and the second substrate. The separator is disposed between the peripheral area and the second substrate and is embedded in the sealing layer. Wherein, with respect to a visible light, a difference between a transmittance of the sealing layer and a transmittance of the optical layer is less than 5%.

The electronic device of the present disclosure may be applied in various types of electronic apparatus. In order to make the features and advantages of some embodiments of the present disclosure more understand, some embodiments of the present disclosure are listed below in conjunction with the accompanying drawings, and are described in detail as follows.

### BRIEF DESCRIPTION OF THE DRAWINGS

The present disclosure can be more fully understood from the following detailed description when read in conjunction with the accompanying drawings. It should be noted that, according to the standard practice in the industry, the various features are not drawn to scale. In fact, the dimensions of the various features may be arbitrarily increased or reduced for clarity.

FIG. 1 is a schematic top view of an electronic device according to some embodiments of the present disclosure.

FIG. 2 is a schematic top view of a region of an electronic device according to some embodiments of the present disclosure.

FIG. 3 is a schematic cross-sectional view of an electronic device according to some embodiments of the present disclosure.

FIG. 4 is a schematic cross-sectional view of an electronic device according to some embodiments of the present disclosure.

FIG. 5 is a schematic top view of an electronic device according to some embodiments of the present disclosure.

FIG. 6 is a schematic cross-sectional view of an electronic device according to some embodiments of the present disclosure.

FIG. 7 is a schematic cross-sectional view of an electronic device according to some embodiments of the present disclosure.

FIG. 8 is a schematic top view of an electronic device according to some embodiments of the present disclosure.

FIG. 9 is a schematic cross-sectional view of an electronic device according to some embodiments of the present disclosure.

FIG. 10 is a schematic cross-sectional view of an electronic device according to some embodiments of the present disclosure.

FIG. 11 is a schematic top view of an electronic device according to some embodiments of the present disclosure.

FIG. 12 is a schematic cross-sectional view of an electronic device according to some embodiments of the present disclosure.

FIG. 13 is a schematic cross-sectional view of an electronic device according to some embodiments of the present disclosure.

FIG. 14 is a schematic cross-sectional view of an electronic device according to some embodiments of the present disclosure.

FIG. 15 is a schematic cross-sectional view of an electronic device according to some embodiments of the present disclosure.

### DETAILED DESCRIPTION

Electronic devices of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements to clearly describe the present disclosure. However, the use of these similar or corresponding reference numerals is only for the purpose of simply and clearly description of some embodiments of the present disclosure, and does not imply any correlation between the different embodiments or structures discussed.

It should be understood that relative terms, such as “lower”, “bottom”, “higher”, or “top” may be used in various embodiments to describe the relative relationship of one element of the drawings to another element. It will be understood that if the device in the drawings were turned upside down, elements described on the “lower” side would become elements on the “upper” side. The embodiments of the present disclosure can be understood together with the drawings, and the drawings of the present disclosure are also regarded as a portion of the disclosure.

Furthermore, when it is mentioned that a first material layer is located “on” or “over” a second material layer, it may include the embodiment which the first material layer and the second material layer are in direct contact and the embodiment which the first material layer and the second material layer are not in direct contact with each other, that is one or more layers of other materials is between the first material layer and the second material layer. However, if the first material layer is directly on the second material layer, it means that the first material layer and the second material layer are in direct contact.

In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to bonding and connection can also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The phrase “a range between a first value and a second value”, “between a first value and a second value”, or “a first value˜a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Certain terms may be used throughout the specification and claims in the present disclosure to refer to specific elements. A person of ordinary skills in the art should be understood that electronic device manufacturers may refer to the same element by different terms. The present disclosure does not intend to distinguish between elements that have the same function but with different terms. In the following description and claims, terms such as “including”, “comprising”, and “having” are open-ended words, so they should be interpreted as meaning “including but not limited to . . . ”. Therefore, when the terms “including”, “comprising”, and/or “having” is used in the description of the present disclosure, it designates the presence of corresponding features, regions, steps, operations, and/or elements, but does not exclude the presence of one or more corresponding features, regions, steps, operations, and/or elements.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For convenience of description, hereinafter, the X-axis direction is the first direction (width direction) D1, the Y-axis direction is the second direction (length direction) D2, and the Z-axis direction is the third direction (height/thickness direction) D3. In some embodiments, the schematic top views described herein are schematic views of the XY plane, the schematic cross-sectional views described herein are schematic views of the XZ plane. In some embodiments, a normal direction of the first substrate and/or the second substrate may be the third direction D3.

In some embodiments, according to the embodiments of the present disclosure, relative setting relationship between elements, a depth, a thickness, a width, or a height of each element, and a spacing or a distance between elements may be measured by using an optical microscope (OM), a scanning electron microscope (SEM), a film thickness profiler (α-step), ellipsometer, or other suitable methods. According to some embodiments, a cross-sectional structure image including an element to be measured may be obtained by using the scanning electron microscope, and then the depth, the thickness, the width, or the height of the element, and the spacing or the distance between elements may be measured.

In some embodiments, according to the embodiments of the present disclosure, the transmittance (unit: %) of each element may be measured by using ultraviolet-visible spectrometers or other suitable methods. In some embodiments, according to embodiments of the present disclosure, the refractive index (n value) (unit: dimensionless) of each element may be measured by using thin film analyzer or other suitable methods. Wherein, the refractive index may represent the ratio (n=c/v) of the speed of light in vacuum (c) to the phase velocity of light after entering the medium (v).

In some embodiments, the electronic device of the present disclosure may include a display module, a back light module, an antenna module, a sensing module, or a titling module, but the present disclosure is not limited thereto. The electronic device may be a foldable or flexible electronic device. The display module may be a non-self-luminous display module or a self-luminous display module. The antenna module may be a liquid-crystal antenna module or a non-liquid-crystal antenna module. The sensing device may be a sensing module for sensing capacitance, light, heat, or ultrasonic waves, but the present disclosure is not limited thereto. The electronic elements may include passive elements and active elements, such as capacitors, resistors, inductors, diodes, transistors, and the like. The diodes may include light-emitting diodes or photodiodes. The light-emitting diodes may include, for example, organic light-emitting diodes (OLEDs), mini light-emitting diodes (mini LEDs), micro light-emitting diodes (micro LEDs), or quantum dot light-emitting diodes (quantum dot LED), but the present disclosure is not limited thereto. The titling module may be, for example, a display titling module or an antenna titling module, but the present disclosure is not limited thereto.

In addition, the shape of the electronic device may be rectangular, circular, polygonal, a shape with curved edges, or another suitable shape. The electronic device may have a peripheral system, such as a processing system, a driving system, a controlling system, a light source system, a shelf system, or the like to support the display module or the titling module.

It should be understood that, for clarity of explanation, some elements of the electronic device may be omitted in the drawings, and some elements are schematically illustrated. In some embodiments, additional elements may be added to the electronic device described below. In other embodiments, some elements of the electronic device described below may be replaced or omitted.

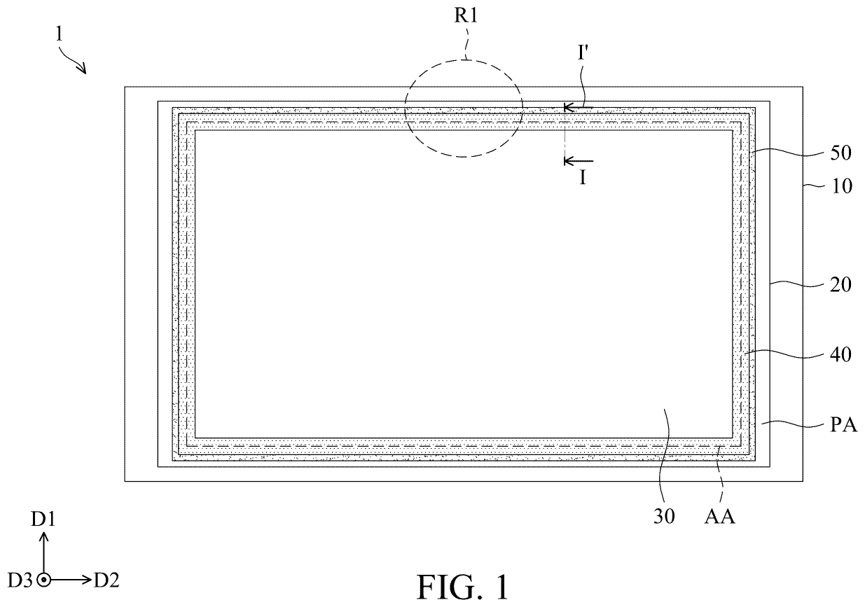

Referring to FIG. 1, it is a schematic top view of an electronic device 1 according to some embodiments of the present disclosure. In some embodiments, the electronic device 1 may include a first substrate 10, a second substrate 20, and a bonding element. In some embodiments, the second substrate 20 may be disposed relative to (for example, opposite to) the first substrate 10, and the bonding element may be disposed between the second substrate 20 and the first substrate 10. In some embodiments, the first substrate 10 and the second substrate 20 may be arranged along the third direction D3. In some embodiments, the first substrate 10 may include an active area AA and a peripheral area PA. In some embodiments, the peripheral area PA may surround the active area AA. In some embodiments, the peripheral area PA may completely surround the active area AA, or the peripheral area PA may surround a portion of the active area AA and expose another portion of the active area AA. In some embodiments, other elements such as pads may be further disposed in the peripheral area PA of the first substrate 10.

In some embodiments, the bonding element may include an optical layer 30, a first sealing layer 40, and/or a second sealing layer 50, but the present disclosure is not limited thereto. In some embodiments, as shown in FIG. 1, the first sealing layer 40 may be disposed in both the active area AA and the peripheral area PA. In some embodiments, as shown in FIG. 1, the second sealing layer 50 may be disposed in the peripheral area PA and may be spaced apart from the active area AA with a distance. In some embodiments, the second sealing layer 50 may surround the first sealing layer 40. In some embodiments, when viewed in a top view, the first sealing layer 40 and/or the second sealing layer 50 may have a frame shape, but the present disclosure is not limited thereto. In some embodiments, the first sealing layer 40 may be disposed between the optical layer 30 and the second sealing layer 50.

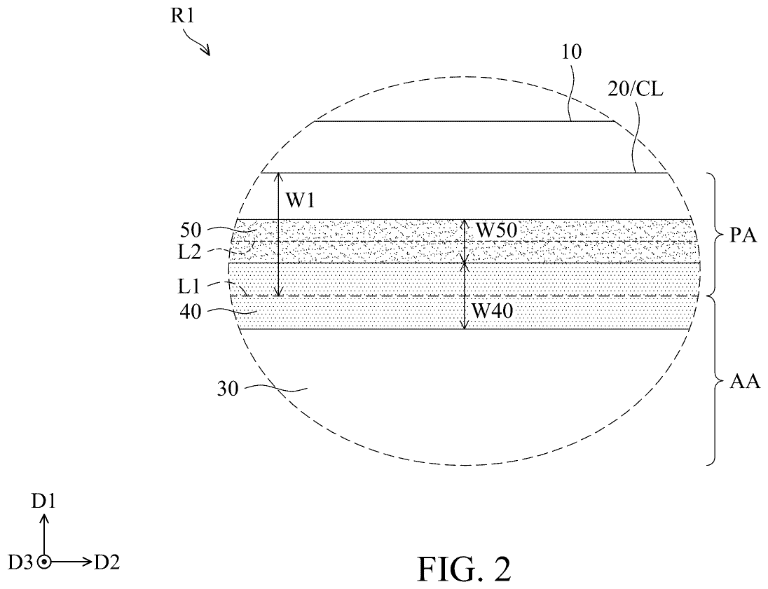

Referring to FIG. 2, it is a schematic top view of a region R1 of the electronic device 1 according to some embodiments of the present disclosure. In some embodiments, a cutting line CL may extend along the second direction D2, and subsequent cutting processes may be performed along the cutting line CL. In some embodiments, the cutting line CL may overlap with an edge of the second substrate 20 in the third direction D3. In some embodiments, the cutting process may include a laser cutting process, a blade cutting process, other suitable cutting processes, or combinations thereof, but the present disclosure is not limited thereto. In some embodiments, in the first direction D1, the cutting line CL and the active area AA of the first substrate 10 may be spaced apart from each other with a width W1. In some embodiments, the width W1 may be between 1200 um˜2000 um. For example, the width W1 may be 1200 um, 1400 um, 1600 um, 1800 um, 2000 um, or any value or any range of values between the aforementioned values, but the present disclosure is not limited thereto.

In some embodiments, as shown in FIG. 2, the first sealing layer 40 may have a width W40 in the first direction D1. In some embodiments, the width W40 of the first sealing layer 40 may be between 800 um˜1200 um. For example, the width W40 may be 800 um, 900 um, 1000 um, 1100 um, 1200 um, or any value or any range of values between the aforementioned values, but the present disclosure is not limited thereto. In some embodiments, a first virtual center line L1 of the first sealing layer 40 is shown, wherein in the first direction D1, the first virtual center line L1 may equally divide the width W40 of the first sealing layer 40. Therefore, the material of the first sealing layer 40 may be applied (for example, coated) along the first virtual center line L1 of the first sealing layer 40. In some embodiments, the first virtual center line L1 may overlap with the edge of the active area AA.

In some embodiments, as shown in FIG. 2, the second sealing layer 50 may have a width W50 in the first direction D1. In some embodiments, the width W50 of the second sealing layer 50 may be between 550 um˜950 um. For example, the width W50 may be 550 um, 650 um, 750 um, 850 um, 950 um, or any value or any range of values between the aforementioned values, but the present disclosure is not limited thereto. In some embodiments, a second virtual center line L2 of the second sealing layer 50 is shown, wherein in the first direction D1, the second virtual center line L2 may equally divide the width W50 of the second sealing layer 50. Therefore, the material of the second sealing layer 50 may be applied (for example, coated) along the second virtual center line L2 of the second sealing layer 50.

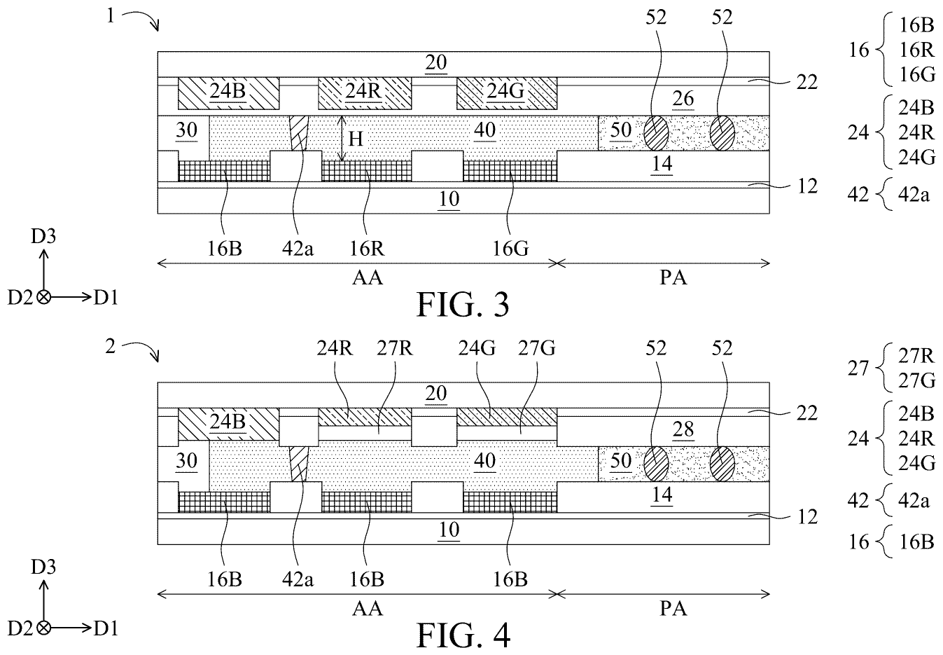

Referring to FIG. 3, it is a schematic cross-sectional view of an electronic device 1 according to some embodiments of the present disclosure. Wherein, FIG. 3 is a schematic cross-sectional view taken along the section I-I′ shown in FIG. 1. In some embodiments, the first substrate 10 and/or the second substrate 20 may include glass, quartz, sapphire, ceramic, polyimide (PI), polycarbonate (PC), polyethylene terephthalate (PET), polypropylene (PP), liquid crystal polymer (LCP), other suitable materials, or combinations thereof, but the present disclosure is not limited thereto. In some embodiments, the substrate may include a light-transmissive substrate, a semi-light-transmissive substrate, or an opaque substrate. For example, the first substrate 10 and the second substrate 20 may include glass.

In some embodiments, a conductive layer 12 may be disposed on the first substrate 10. In some embodiments, the material of the conductive layer 12 may include metal, metal nitride, semiconductor material, other suitable conductive materials, or combinations thereof, but the present disclosure is not limited thereto. In some embodiments, the material of the conductive layer 12 may include gold (Au), nickel (Ni), platinum (Pt), palladium (Pd), iridium (Ir), titanium (Ti), chromium (Cr), tungsten (W), aluminum (Al), copper (Cu), molybdenum (Mo), titanium (Ti), silver (Ag), magnesium (Mg), alloys thereof, compounds thereof, or combinations thereof, but the present disclosure is not limited thereto. In some embodiments, the material of the conductive layer 12 may include transparent conductive oxide (TCO). For example, the transparent conductive oxide may include indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), other suitable transparent conductive materials, or combinations thereof, but the present disclosure is not limited thereto. In some embodiments, a pixel definition layer 14 may be disposed on the conductive layer 12. In some embodiments, the pixel definition layer 14 may have openings, and the openings may be used to expose subsequently formed electronic units.

In some embodiments, a plurality of electronic units 16 may be disposed on the first substrate 10 and disposed in the openings of the pixel definition layer 14. In some embodiments, a plurality of electronic units 16 may be disposed between the first substrate 10 and the second substrate 20. In some embodiments, the plurality of electronic units 16 may be disposed in the active area AA of the first substrate 10. In other words, the area of the first substrate 10 in which the plurality of electronic units 16 is disposed may be used as the active area AA of the first substrate 10. In some embodiments, the plurality of electronic units 16 may be disposed between the active area AA of the first substrate 10 and the second substrate 20.

In some embodiments, the electronic unit 16 may be an element with a function of emitting light. In some embodiments, the electronic unit may include an organic light-emitting diode (OLED), a mini light-emitting diode (mini LED), a micro light-emitting diode (micro LED), or a quantum dot light-emitting diode. (quantum dot LED), other suitable light-emitting elements, or combinations thereof, but the present disclosure is not limited thereto. In some embodiments, since the electronic unit 16 may be a small-sized light-emitting element, the conductive layer 12 and the pixel definition layer 14 corresponding to the electronic unit 16 have a small pitch. In some embodiments, the electronics unit 16 may include electronics units that emit different colors of light. In some embodiments, the electronic unit 16 may include an electronic unit 16B that emits blue light, an electronic unit 16R that emits red light, and an electronic unit 16G that emits green light. In some embodiments, the first substrate 10, the conductive layer 12, the pixel definition layer 14, and the electronic unit 16 may be collectively referred to as a transistor module.

In some embodiments, a light-shielding layer 22 may be disposed on the second substrate 20. In some embodiments, the light-shielding layer 22 may be a black matrix, a black glue, or a black photoresist material. In some embodiments, with respect to the visible light, the transmittance of the light-shielding layer 22 may be less than 30%. For example, the transmittance of the light-shielding layer 22 for visible light is less than 30%, 25%, 20%, 15%, 10%, 5%, 3%, 1%, or any value between the aforementioned values, but the present disclosure is not limited thereto. Therefore, when the light-shielding layer 22 has low transmittance, the ambient light irradiating the conductive layer 12 may be reduced. In some embodiments, the light-shielding layer 22 may have openings, and the openings may be used to expose subsequently formed color filter layer.

In some embodiments, a color filter layer 24 may be disposed on the second substrate 20 and may be disposed in the openings of the light-shielding layer 22. In some embodiments, the color filter layer 24 may include a blue filter layer 24B, a red filter layer 24R, and a green filter layer 24G corresponding to the blue light, the red light, and the green light, respectively. In some embodiments, a planarization layer 26 may be disposed on the color filter layer 24 and the light-shielding layer 22 so that the second substrate 20 has a flat surface. In some embodiments, the planarization layer 26 may include an optical clear material. In some embodiments, the second substrate 20, the light-shielding layer 22, the color filter layer 24, and the planarization layer 26 may be collectively referred to as a color filter module.

In some embodiments, as shown in FIG. 3, the optical layer 30 may be disposed between a portion of the electronic units 16 and the second substrate 20. In some embodiments, the optical layer 30 may cover a portion of the electronic units 16 and may expose a portion of the electronic units 16. In some embodiments, the optical layer 30 may include an optical clear adhesive (OCA), an optical clear resin (OCR), a pressure sensitive adhesive (PSA), but the present disclosure is not limited thereto.

In some embodiments, with respect to the visible light, the transmittance of the optical layer 30 may be greater than or equal to 95% and less than or equal to 100% (95%≤transmittance of the optical layer 30≤100%). For example, the transmittance of the optical layer 30 may be 95%, 96%, 97%, 98%, 99%, 99.5%, 99.9%, 99.99%, or any value or any range of values between the aforementioned values, but the present disclosure is not limited thereto. In some embodiments, the visible light may be a light with a wavelength between 380 nm and 780 nm. For example, the wavelength of the visible light may be 380 nm, 400 nm, 500 nm, 550 nm, 600 nm, 700 nm, 780 nm, or any value or any range of values between the aforementioned values, but the present disclosure is not limited thereto. In some embodiments, the refractive index (n value) of the optical layer 30 may be between 1.3˜1.6. For example, the n value of the optical layer 30 may be 1.3, 1.35, 1.4, 1.45, 1.5, 1.51, 1.52, 1.53, 1.54, 1.55, 1.56, 1.57, 1.58, 1.59, 1.6, or any value or any range of values between the aforementioned values, but the present disclosure is not limited thereto.

In some embodiments, as shown in FIG. 3, the first sealing layer 40 may be disposed between another portion of the electronic units 16 and the second substrate 20. In some embodiments, the first sealing layer 40 may be disposed on the electronic units 16 exposed by the optical layer 30. In some embodiments, the optical layer 30 may cover a portion of the electronic units 16 and the first sealing layer 40 may cover a remaining portion of the electronic units 16. In some embodiments, the first sealing layer 40 may surround the optical layer 30.

In some embodiments, with respect to the visible light, the transmittance of the first sealing layer 40 may be greater than or equal to 95% and less than or equal to 100%. For example, the transmittance of the first sealing layer 40 may be 95%, 96%, 97%, 98%, 99%, 99.5%, 99.9%, 99.99%, or any value or any range of values between the aforementioned values, but the present disclosure is not limited thereto. In some embodiments, the first sealing layer 40 may include a silicone resin, an epoxy resin, an acrylic resin, other suitable materials, or combinations thereof, but the present disclosure is not limited thereto. In some embodiments, the refractive index (n value) of the first sealing layer 40 may be between 1.3˜1.6. For example, the n value of the first sealing layer 40 may be 1.3, 1.35, 1.4, 1.45, 1.5, 1.51, 1.52, 1.53, 1.54, 1.55, 1.56, 1.57, 1.58, 1.59, 1.6, or any value or any range of values between the aforementioned values, but the present disclosure is not limited thereto.

In some embodiments, with respect to the visible light, the difference between the transmittance of the first sealing layer 40 and the transmittance of the optical layer 30 may be less than 5% (|the transmittance of the first sealing layer 40−the transmittance of the optical layer 30|<5%) to avoid the existence of seams when lights respectively pass through the first sealing layer 40 and the optical layer 30 adjacent with each other, thereby improving the visual effect of the user observing the electronic device 1. For example, the difference between the transmittance of the first sealing layer 40 and the transmittance of the optical layer 30 may be less than 5%, 4%, 3%, 2%, 1%, 0.5%, or less, or any value or any range of values between the aforementioned values, but the present disclosure is not limited thereto. In some embodiments, with respect to the visible light, the transmittance of the first sealing layer 40 may be less than the transmittance of the optical layer 30. In some embodiments, with respect to the visible light, the transmittance of the first sealing layer 40 may be less than the transmittance of the optical layer 30 by 5%.

In some embodiments, the difference between the refractive index of the first sealing layer 40 and the refractive index of the optical layer 30 may be less than 0.1 (|the refractive index of the first sealing layer 40−the refractive index of the optical layer 30|<0.1) to avoid the existence of seams when lights respectively pass through the first sealing layer 40 and the optical layer 30 adjacent with each other, thereby improving the visual effect. For example, the difference between the refractive index of the first sealing layer 40 and the refractive index of the optical layer 30 may be less than 0.1, 0.09, 0.08, 0.07, 0.06, 0.05, 0.04, 0.03, or less, or any value or any range of values between the aforementioned values, but the present disclosure is not limited thereto.

In some embodiments, as shown in FIG. 3, the second sealing layer 50 may be disposed between the first substrate 10 and the second substrate 20, and the second sealing layer 50 may surround the first sealing layer 40. In some embodiments, the second sealing layer 50 may be disposed on the peripheral area PA of the first substrate 10. In some embodiments, in the third direction D3, a boundary of the first sealing layer 40 and the second sealing layer 50 does not overlap with the electronic unit 16. In some embodiments, the projected position of the boundary of the first sealing layer 40 and the second sealing layer 50 on the first substrate 10 is spaced apart from the projected position of the electronic unit 16 on the first substrate 10. In some embodiments, since the first sealing layer 40 may be disposed between the optical layer 30 and the second sealing layer 50, the optical layer 30 is spaced apart from the second sealing layer 50 by a distance.

In some embodiments, the material of the second sealing layer 50 may be the same as or different from the material of the first sealing layer 40. In some embodiments, the second sealing layer 50 may include a silicone resin, an epoxy resin, an acrylic resin, other suitable materials, or combinations thereof, but the present disclosure is not limited thereto. In other embodiments, the second sealing layer 50 may further include fillers to enhance the structural strength of the second sealing layer 50. Therefore, the structural strength of the second sealing layer 50 may be greater than the structural strength of the first sealing layer 40. In some embodiments, the fillers may include silica-based materials. For example, the fillers may include silica particles. In this embodiment, since the fillers are not included in the first sealing layer 40, the transmittance of the first sealing layer 40 may be greater than the transmittance of the second sealing layer 50.

In some embodiments, the second sealing layer 50 may further include a plurality of spacer particles 52, and the plurality of spacer particles 52 may be dispersed in the second sealing layer 50 to improve the structural strength and support of the second sealing layer 50. In some embodiments, the volume of the spacer particles 52 may account for 3% or less of the volume of the second sealing layer 50. For example, the volume of the spacer particles 52 accounts for 3%, 2.5%, 2%, 1.5%, 1%, 0.75%, 0.5%, 0.1%, or any value or any range of values between the aforementioned values, but the present disclosure is not limited thereto. In some embodiments, the spacer particles 52 may include silica-based materials. For example, the spacer particles 52 may include silica balls. In some embodiments, the size of the spacer particles 52 may be significantly greater than the size of the fillers. In some embodiments, the size of spacer particles 52 may depend on a height H (that is, the cell gap) between the planarization layer 26 and the electronic cells 16. In some embodiments, the diameter of the spacer particles 52 may be 0.5˜0.95 times the height H. For example, the diameter of the spacer particles 52 may be 0.5 times, 0.6 times, 0.7 times, 0.8 times, 0.9 times, 0.95 times, or any value or any range of values between the aforementioned values, but the present disclosure is not limited thereto.

In some embodiments, as shown in FIG. 3, the electronic device 1 may include a separator 42 surrounding the optical layer 30, and the separator 42 may include a first spacer element 42a. In some embodiments, the first spacer element 42a may be disposed between the active area AA of the first substrate 10 and the second substrate 20. In some embodiments, the first spacer element 42a may provide support and structural strength between the first substrate 10 and the second substrate 20. In some embodiments, the first spacer element 42a may include polyimide (PI), benzocyclobutene, polymethylmethacrylate (PMMA), polyamide, acrylic acid, phenolic resin, other suitable materials, or combinations thereof, but the present disclosure is not limited thereto. In some embodiments, as shown in FIG. 3, when viewed in a cross-sectional view, the shape of the first spacer element 42a may include a rectangle, a right trapezoid, an inverted trapezoid, a semicircle, other suitable shapes, or combinations thereof, but the present disclosure is not limited thereto.

In some embodiments, the transistor module and the color filter module may be formed independently. In some embodiments, the separator 42 may be formed on the color filter module. For example, the separator 42 may be formed on the surface of the planarization layer 26 in the color filter module away from the second substrate 20 by using a photolithography process. In some embodiments, after the separator 42 is formed on the color filter module, the materials of the bonding elements (for example, materials of the optical layer 30, materials of the first sealing layer 40, and materials of the second sealing layer 50) are provided on the color filter module. For example, the materials of the bonding elements may be provided on the color filter module by coating, injection, other suitable processes, or combinations thereof. In some embodiments, a bonding process is performed to bond the transistor module to the color filter module. For example, the transistor module is turned upside down so that the electronic unit 16 of the transistor module faces the color filter module and bonds with the color filter module. In some embodiments, a photocuring process is performed on the bonded transistor module and the color filter module. In some embodiments, after performing the photocuring process, a thermal curing process is further performed. In some embodiments, the cutting process (as shown in FIG. 2) may be performed on the cured transistor module and the color filter module to obtain a plurality of electronic devices.

It should be noted that, since the opening rate in the peripheral area PA is less than the opening rate in the active area AA, the conductive layer 12 and the pixel definition layer 14 in the peripheral area PA will block a light emitted during the photocuring process, making the bonding element located between the conductive layer 12 and the pixel definition layer 14 in the peripheral area PA difficult to be photocured. In addition, when the electronic device includes small-sized light-emitting elements, the opening rate in the active area AA will be further decreased, making the bonding element located between the conductive layer 12 and the pixel definition layer 14 in the peripheral area PA more difficult to be photocured. Therefore, if the bonding element is difficult to be photocured, different materials in the bonding elements will dissolve with each other, causing dissolution problems. Furthermore, since the bonding process may be performed at a pressure below the normal pressure (for example, less than 1 atm), the materials of the bonding elements will spillover (overflow) onto the cutting line (the cutting line CL shown in FIG. 2). Therefore, the materials of the bonding elements will affect the subsequent cutting process, thereby degrading the electronic device.

In a comparative example, the optical layer 30 is disposed in the active area AA and the peripheral area PA of the first substrate 10, the second sealing layer 50 is disposed in the peripheral area PA of the first substrate 10, the optical layer 30 and the second sealing layer 50 are in direct contact, and the first sealing layer 40 is omitted. Since the light emitted during the photocuring process is blocked, it is difficult for the second sealing layer 50 to be effectively photocured. Therefore, dissolution may occur between the optical layer 30 and the second sealing layer 50 and/or the optical layer 30 and the second sealing layer 50 may spillover onto the cutting line (the cutting line CL shown in FIG. 2).

However, the present disclosure disposes the first sealing layer 40 between the optical layer 30 and the second sealing layer 50 and in the active area AA, so that the first sealing layer 40 is located in the active area AA with a higher opening rate. Therefore, the first sealing layer 40 may be irradiated by the light emitted during the photocuring process, thereby effectively photocuring the first sealing layer 40 to separate the optical layer 30 and the second sealing layer 50 from each other. Then, the thermal curing process is performed, so that the optical layer 30 and the second sealing layer 50 are thermally cured and the first sealing layer 40 is ensured to be cured. Accordingly, the present disclosure may avoid the problems of dissolution and/or spillover caused by direct contact between the optical layer 30 and the second sealing layer 50.

In the following, the same or similar reference numerals and descriptions are omitted.

Referring to FIG. 4, it is a schematic cross-sectional view of an electronic device 2 according to some embodiments of the present disclosure. Wherein, FIG. 4 is a schematic cross-sectional view taken along the section I-I′ shown in FIG. 1. In some embodiments, as shown in FIG. 4, the electronic device 2 may include a color conversion layer 27 and a separation layer 28. In some embodiments, the separation layer 28 may be disposed on the light-shielding layer 22 to define a space for accommodating the color conversion layer 27. In some embodiments, the separation layer 28 may include black resin, gray resin, white resin, metal, other suitable materials, or combinations thereof, but the present disclosure is not limited thereto. In some embodiments, the color conversion layer 27 may be disposed on the color filter layer 24. In some embodiments, the color conversion layer 27 may include a red color conversion layer 27R and a green color conversion layer 27G. In some embodiments, the red color conversion layer 27R may be disposed on the red color filter layer 24R and may include red quantum dots. In some embodiments, the green color conversion layer 27G may be disposed on the green color filter layer 24G and may include green quantum dots. Therefore, the wavelength and color of the blue light emitted from the electronic unit 16B may be converted by the color conversion layer 27. Optionally, a light diffusion layer may be disposed on the blue color filter layer 24B, and the light diffusion layer may include diffusion particles, for example, titanium dioxide particles.

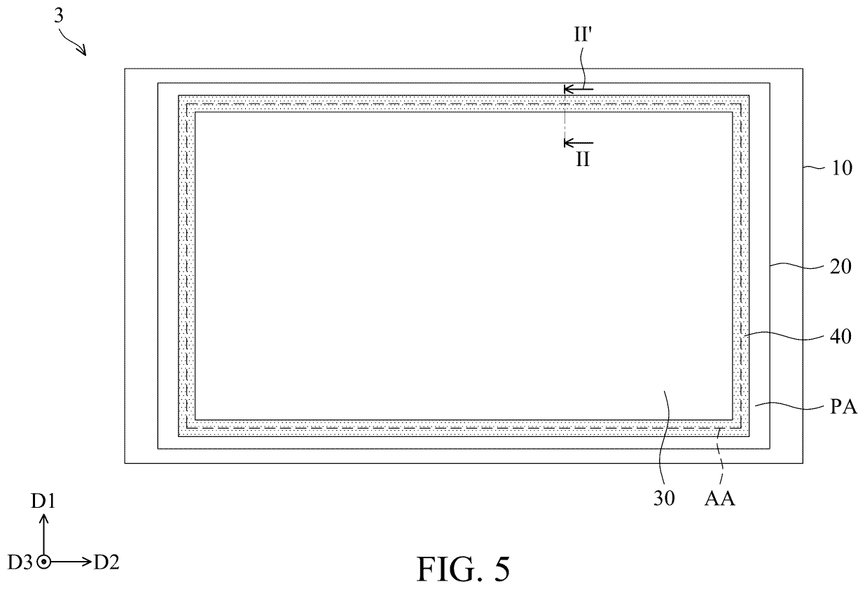

Referring to FIG. 5, it is a schematic top view of an electronic device 3 according to some embodiments of the present disclosure. For convenience of explanation, some elements may be omitted in FIG. 5. In some embodiments, the first sealing layer 40 may be provided in both the active area AA and the peripheral area PA, and the second sealing layer 50 may be omitted. In some embodiments, the optical layer 30 may be disposed in the active area AA. Accordingly, the present disclosure may avoid the problems of dissolution and/or spillover caused by direct contact between the optical layer 30 and the second sealing layer. For example, a portion of the first sealing layer 40 in the active area AA may be photocured in the photocuring process, and then the remaining portion of the first sealing layer 40 in the peripheral area PA (and the optical layer 30) is thermally cured during the thermal curing process.

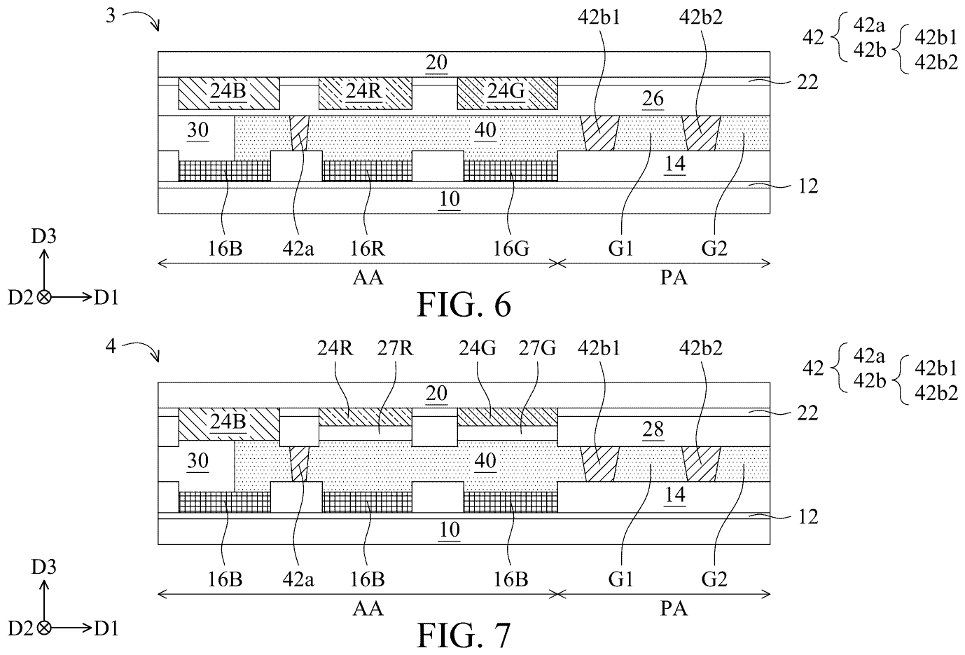

Referring to FIG. 6, it is a schematic cross-sectional view of an electronic device 3 according to some embodiments of the present disclosure. Wherein, FIG. 6 is a schematic cross-sectional view taken along the section II-II′ shown in FIG. 5. In some embodiments, as shown in FIG. 6, the optical layer 30 may be disposed between a portion of the electronic units 16 and the second substrate 20. In some embodiments, the first sealing layer 40 may be disposed between another portion of the electronic units 16 and the second substrate 20, and may be disposed between the peripheral area PA of the first substrate 10 and the second substrate 20. In some embodiments, the first sealing layer 40 may be disposed on the electronic units 16 exposed by the optical layer 30.

In some embodiments, as shown in FIG. 6, the electronic device 3 may include the separator 42 surrounding the optical layer 30. In some embodiments, the separator 42 may include a first spacer element 42a and a second spacer element 42b, and the second spacer element 42b may surround the first spacer element 42a. In some embodiments, a portion of the separator 42 (that is, the first spacer element 42a) may be disposed between the active area AA of the first substrate 10 and the second substrate 20, and may be embedded in the first sealing layer 40. In some embodiments, a portion of the separator 42 (that is, the second spacer element 42b) may be disposed between the peripheral area PA of the first substrate 10 and the second substrate 20, and may be embedded in the first sealing layer 40. In some embodiments, the materials and formation methods of the first spacer element 42a and the second spacer element 42b may be the same or different. In some embodiments, the first spacer element 42a and the second spacer element 42b may include the same material and may be formed in the same process.

In some embodiments, the second spacer element 42b may include a plurality of spacers 42b1 and 42b2, and the plurality of spacers 42b1 and 42b2 may be arranged around the first sealing layer 40. In some embodiments, the spacers 42b1, 42b2 may be disposed on a side of the first sealing layer 40 away from the optical layer 30. In some embodiments, the spacer 42b1 may be closer to the optical layer 30 than the spacer 42b2.

In some embodiments, as shown in FIG. 6, after performing the bonding process and before performing the photocuring process, the second spacer element 42b may be used to block the material of the first sealing layer 40 from spillover. Since the second spacer element 42b may include the plurality of spacers 42b1 and 42b2, the process window may be further improved. In some embodiments, the first sealing layer 40 may fill the gaps G1 and G2. In other embodiments, the first sealing layer 40 may not completely fill the gap G1, or the first sealing layer 40 may not fill the gap G1. In other embodiments, the first sealing layer 40 may not fill the gap G1, and the first sealing layer 40 may not fill the gap G2. Therefore, the process window of providing the material of the first sealing layer 40 on the color filter module may be improved and/or the process window of performing the cutting process may be improved.

Referring to FIG. 7, it is a schematic cross-sectional view of an electronic device 4 according to some embodiments of the present disclosure. Wherein, FIG. 7 is a schematic cross-sectional view taken along the section II-II′ shown in FIG. 5. In some embodiments, as shown in FIG. 7, the electronic device 4 may include the separator 42 surrounding the optical layer 30. In some embodiments, the first sealing layer 40 may completely fill, partially fill, or not fill the gap G1 and/or the gap G2.

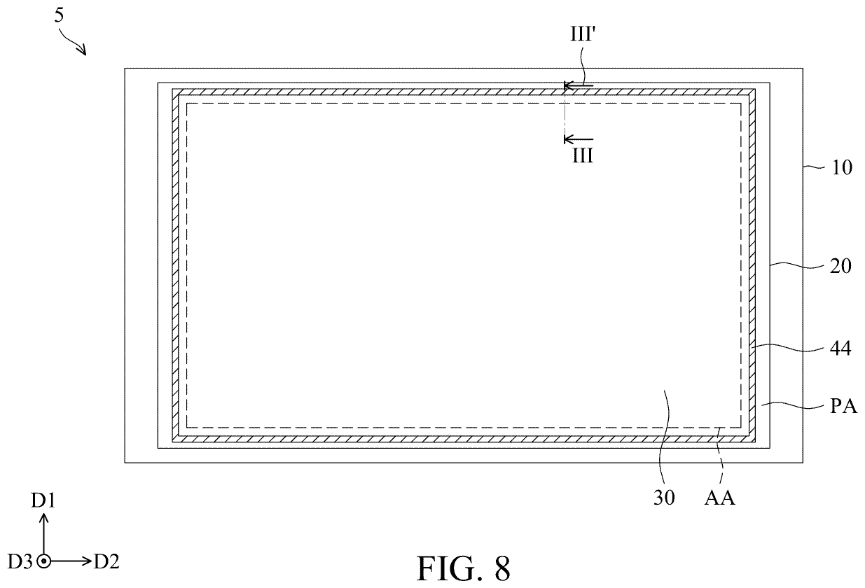

Referring to FIG. 8, it is a schematic top view of an electronic device 5 according to some embodiments of the present disclosure. For convenience of explanation, some elements may be omitted in FIG. 8. In some embodiments, the electronic device 5 may further include a blocking wall 44 disposed in the optical layer 30, and the first sealing layer 40 and the second sealing layer 50 are omitted. In some embodiments, the blocking wall 44 may be disposed in the peripheral area PA of the first substrate 10. In some embodiments, the material and formation method of the blocking wall 44 may be the same as or different from the first spacer element 42a. In some embodiments, the blocking wall 44 and the first spacer element 42a may include the same material and may be formed in the same process. In some embodiments, when viewed in a top view, the blocking wall 44 may have a frame shape, but the present disclosure is not limited thereto. Accordingly, the present disclosure may avoid the problems of dissolution and/or spillover caused by direct contact between the optical layer 30 and the second sealing layer. For example, since the first sealing layer 40 and the second sealing layer 50 are omitted, the dissolution and/or spillover will not occur. In addition, the photocuring process may be omitted, and the optical layer 30 may be thermally cured by the thermal curing process.

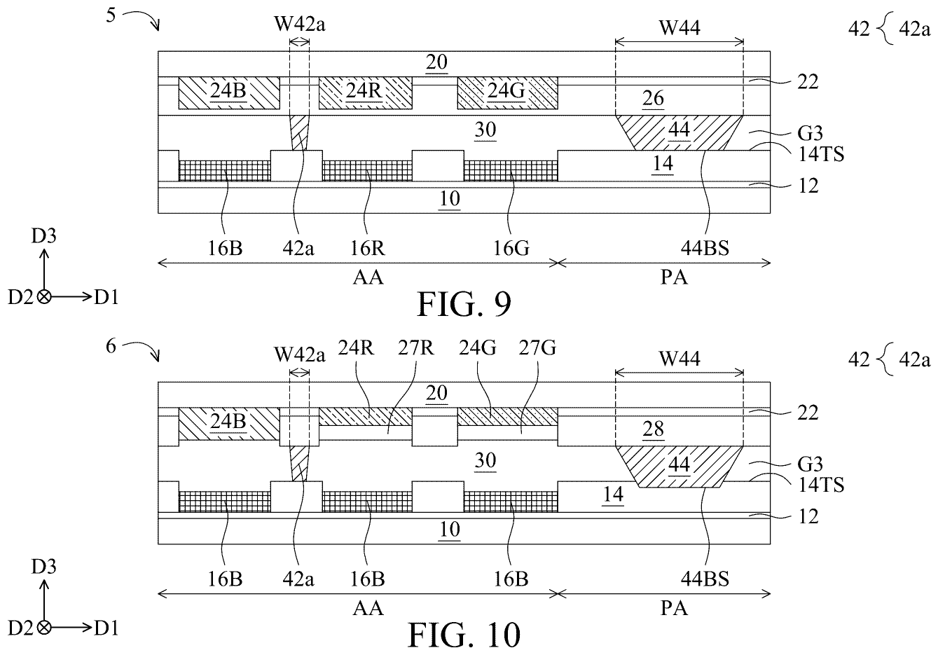

Referring to FIG. 9, it is a schematic cross-sectional view of an electronic device 5 according to some embodiments of the present disclosure. Wherein, FIG. 9 is a schematic cross-sectional view taken along section III-III′ shown in FIG. 8. In some embodiments, the optical layer 30 may be disposed in the active area AA and the peripheral area PA of the first substrate 10. In some embodiments, the blocking wall 44 may surround the first spacer element 42a. In some embodiments, in the first direction D1, the first spacer element 42a may have a width W42a, the blocking wall 44 may have a width W44, and the ratio of the width W44 to the width W42a (the width W44/the width W42a) may be between 1˜100. For example, the ratio of the width W44 to the width W42a may be 1, 5, 10, 20, 30, 40, 50, 60, 70, 80, 90, 100, or any value or any range of values between the aforementioned values, but the present disclosure is not limited thereto. In some embodiments, the bottom surface 44BS of the blocking wall 44 may be aligned with the top surface 14TS of the pixel definition layer 14. In some embodiments, the optical layer 30 may completely fill, partially fill, or not fill a gap G3.

Referring to FIG. 10, it is a schematic cross-sectional view of an electronic device 6 according to some embodiments of the present disclosure. Wherein, FIG. 10 is a schematic cross-sectional view taken along section III-III′ shown in FIG. 8. In some embodiments, the bottom surface 44BS of the blocking wall 44 may be lower than the top surface 14TS of the pixel definition layer 14 such that a portion of the blocking wall 44 is embedded in the pixel definition layer 14. In some embodiments, an etching process may be performed on the pixel definition layer 14 to form a recess (not shown), and then the blocking wall 44 is formed in the recess. In some embodiments, since the pixel definition layer 14 may cover a portion of the side surface of the blocking wall 44, the structural strength of the electronic device may be improved. In some embodiments, the optical layer 30 may completely fill, partially fill, or not fill the gap G3.

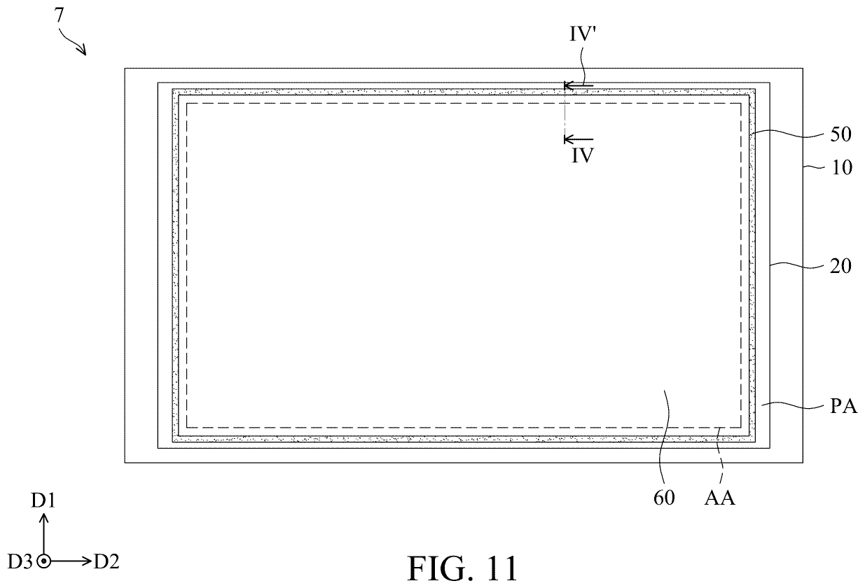

Referring to FIG. 11, it is a schematic top view of an electronic device 7 according to some embodiments of the present disclosure. In some embodiments, the electronic device 7 may include the second sealing layer 50 disposed in the peripheral area PA of the first substrate 10, and the optical layer 30 and the first sealing layer 40 may be omitted. In some embodiments, since the optical layer 30 and the first sealing layer 40 are omitted, there is an air gap 60 between the active area AA of the first substrate 10 and the second substrate 20. Accordingly, the present disclosure may avoid the problems of dissolution and/or spillover caused by direct contact between the optical layer 30 and the second sealing layer 50. For example, since the optical layer 30 is omitted, the dissolution and/or spillover will not occur. In the present disclosure, sufficient structural strength of the electronic device may be provided by the first spacer element 42a, the second sealing layer 50, and the spacer particles 52.

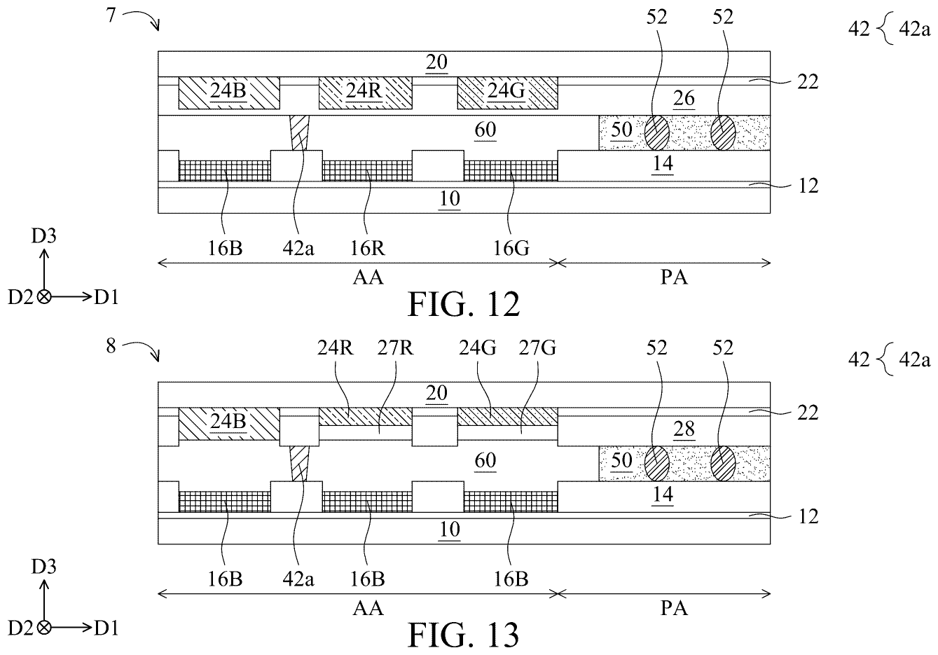

Referring to FIG. 12, it is a schematic cross-sectional view of an electronic device 7 according to some embodiments of the present disclosure. Wherein, FIG. 12 is a schematic cross-sectional view taken along section IV-IV′ shown in FIG. 11. In some embodiments, an air gap 60 may be between the electronic units 16 and the planarization layer 26. In this embodiment, the electronic device 7 may include the second sealing layer 50 disposed in the peripheral area PA of the first substrate 10, and the optical layer 30 and the first sealing layer 40 may be omitted.

Referring to FIG. 13, it is a schematic cross-sectional view of an electronic device 8 according to some embodiments of the present disclosure. Wherein, FIG. 13 is a schematic cross-sectional view taken along section IV-IV′ shown in FIG. 11. In some embodiments, the air gap 60 may be between the electronic units 16 and the separation layer 28. In this embodiment, the electronic device 8 may include the second sealing layer 50 disposed in the peripheral area PA of the first substrate 10, and the optical layer 30 and the first sealing layer 40 may be omitted.

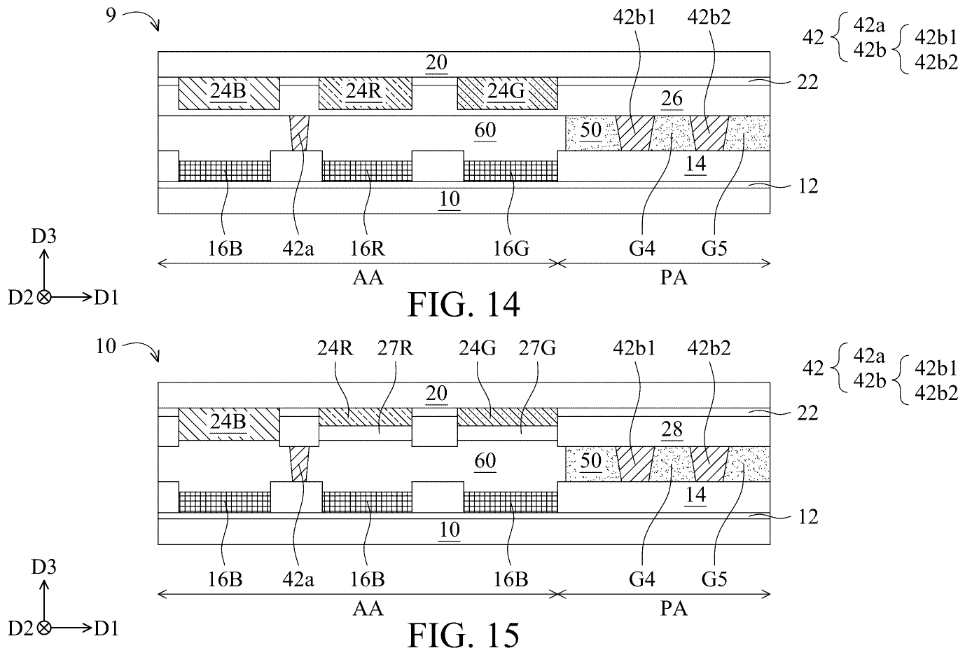

Referring to FIGS. 14 and 15, they are schematic cross-sectional views of electronic devices 9 and 10 according to some embodiments of the present disclosure. Wherein, FIGS. 14 and 15 are respectively schematic cross-sectional views taken along the section IV-IV′ shown in FIG. 11. In some embodiments, as shown in FIGS. 14 and 15, the spacer particles 52 may be replaced by the spacers 42b1 and 42b2.

Accordingly, the present disclosure adjusts the relationships, such as material types, positions, sizes, and the like, of the bonding elements (for example, the optical layer, the first sealing layer, the second sealing layer) between the first substrate and the second substrate, to improve the reliability of the bonding elements, and/or the visual effect, resolution, reliability, yield and/or process window of the electronic devices.

For example, the present disclosure may select the optical layer and the first sealing layer with the specific transmittance difference (for example, <5%) and/or with the specific refractive index (n value) difference (for example, <0.1), to avoid the existence of seams when lights respectively pass through the first sealing layer and the optical layer adjacent with each other. For example, the present disclosure may avoid the problems of dissolution and/or spillover caused by direct contact between the optical layer and the second sealing layer by disposing the first sealing layer between the optical layer and the second sealing layer, by disposing the optical layer and the first sealing layer and omitting the second sealing layer, by disposing the optical layer and omitting the first sealing layer and the second sealing layer, and/or by disposing the air gap and the second sealing layer. For example, the electronic device of the present disclosure may include the spacer particles and the separator (for example, the spacer elements, the spacers) to enhance the structural strength of the electronic device. For example, since the bonding element of the present disclosure may have high transmittance, the electronic device of the present disclosure may be applied to products with narrow frames.

The features among the various embodiments may be arbitrarily combined as long as they do not violate or conflict with the spirit of the disclosure. In addition, the scope of the present disclosure is not limited to the process, machine, manufacturing, material composition, device, method, and step in the specific embodiments described in the specification. A person of ordinary skill in the art will current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic device, comprising:
a first substrate,
a second substrate disposed opposite to the first substrate,
a plurality of electronic units disposed between the first substrate and the second substrate,
an optical layer disposed between a portion of the plurality of electronic units and the second substrate,
a first sealing layer disposed between another portion of the plurality of electronic units and the second substrate and surrounding the optical layer, and
a second sealing layer disposed between the first substrate and the second substrate and surrounding the first sealing layer,
wherein, with respect to a visible light, a difference between a transmittance of the first sealing layer and a transmittance of the optical layer is less than 5%.

2. The electronic device according to claim 1, wherein the second sealing layer comprises a plurality of spacer particles.

3. The electronic device according to claim 2, wherein a volume of the plurality of spacer particles accounts for 3% or less of a volume of the second sealing layer.

4. The electronic device according to claim 2, wherein a diameter of the plurality of spacer particles is 0.5˜0.95 times a cell gap.

5. The electronic device according to claim 1, wherein a boundary between the first sealing layer and the second sealing layer does not overlap with the plurality of electronic units.

6. The electronic device according to claim 1, wherein with respect to the visible light, the transmittance of the first sealing layer is less than the transmittance of the optical layer.

7. The electronic device according to claim 1, wherein with respect to the visible light, the transmittances of the first sealing layer and the optical layer are greater than or equal to 95% and less than or equal to 100%.

8. The electronic device according to claim 1, wherein a difference between a n value of the first sealing layer and a n value of the optical layer is less than 0.1.

9. The electronic device according to claim 1, wherein n values of the first sealing layer and the optical layer are between 1.3˜1.6.

10. The electronic device according to claim 1, wherein a width of the first sealing layer is between 800 um˜1200 um.

11. The electronic device according to claim 1, wherein a width of the second sealing layer is between 550 um˜950 um.

12. The electronic device according to claim 1, wherein the transmittance of the first sealing layer is greater than a transmittance of the second sealing layer.

13. An electronic device, comprising:
a first substrate having an active area and a peripheral area surrounding the active area,
a second substrate disposed opposite to the first substrate,
a plurality of electronic units disposed between the active area and the second substrate,
an optical layer disposed between a portion of the plurality of electronic units and the second substrate,
a sealing layer disposed between another portion of the plurality of electronic units and the second substrate and between the peripheral area and the second substrate, and
a separator disposed between the peripheral area and the second substrate and embedded in the sealing layer,
wherein, with respect to a visible light, a difference between a transmittance of the sealing layer and a transmittance of the optical layer is less than 5%.

14. The electronic device according to claim 13, wherein the separator surrounds the optical layer.

15. The electronic device according to claim 14, wherein the separator comprises a first spacer element and a second spacer element, and the second spacer element surrounds the first spacer element.

16. The electronic device according to claim 13, wherein the separator comprises a plurality of spacers, and the plurality of spacers is arranged around the sealing layer.

17. The electronic device according to claim 13, wherein with respect to the visible light, the transmittance of the sealing layer is less than the transmittance of the optical layer.

18. The electronic device according to claim 13, wherein with respect to the visible light, the transmittances of the sealing layer and the optical layer are greater than or equal to 95% and less than or equal to 100%.

19. The electronic device according to claim 13, wherein a difference between a n value of the sealing layer and a n value of the optical layer is less than 0.1.

20. The electronic device according to claim 13, wherein n values of the sealing layer and the optical layer are between 1.3˜1.6.
